(19) United States
(12) Patent Application Publication
(10) Pub. No.: US 2017/0076919 A1
(43) Pub. Date: Mar. 16, 2017

(54) METHOD OF MANUFACTURING SEMICONDUCTOR DEVICE

(71) Applicant: Renesas Electronics Corporation, Tokyo (JP)

(72) Inventors: Kazuyuki FUJII, lbaraki (JP); Yosuke INOUE, lbaraki (JP)

(21) Appl. No.: 15/264,745

(22) Filed: Sep. 14, 2016

(30) Foreign Application Priority Data
Sep. 15, 2015 (JP) 2015-182220

(51) Int. Cl. H01J 37/32; G01R 31/11; G01R 27/26

(52) U.S. Cl. CPC H01J 37/32917; H01J 37/32082; G01R 27/26; G01R 31/11

(57) ABSTRACT

An abnormal part (component) is identified for a short time. A method of manufacturing a semiconductor device according to one embodiment includes a step of performing a plasma treatment on a semiconductor substrate by using plasma equipment, and a step of inspecting the plasma equipment. The inspection step includes a step of measuring impedance or reflection intensity at each frequency by varying a frequency of an input signal while regarding a RF power supplying line of the plasma equipment as an electrical circuit. Further, the inspection step includes a step of calculating characteristics of impedance or reflection intensity in an arrival location of the signal with respect to an arrival time of the signal by performing an inverse Fourier transform on a measurement result.

### CROSS-REFERENCE TO RELATED APPLICATION

The present application claims priority from Japanese Patent Application No. 2015-182220 filed on Sep. 15, 2015, the content of which is hereby incorporated by reference into this application.

### TECHNICAL FIELD OF THE INVENTION

The present invention relates to a technique for manufacturing a semiconductor device, and in particular to a method of manufacturing a semiconductor device using plasma equipment.

### BACKGROUND OF THE INVENTION

There are a large number of processes using plasma such as etching, CVD (Chemical Vapor Deposition), and sputtering in the manufacturing steps of the semiconductor device. In the plasma equipment for performing various processes by using the plasma, it is important to hold the process performance constant by holding the equipment state constant to produce a good yield product. In addition, mass production of products is performed by using a plurality of pieces of plasma equipment, and therefore it is necessary for the equipment state not to vary in the same process equipment.

On the other hand, it is difficult to directly and quantitatively diagnose and detect the aging of the equipment state of the plasma equipment, the variation of the equipment state in the equipment, or the abnormality in the equipment state. For example, conventionally, the process performance is held to a certain level by performing the equipment maintenance (such as cleaning, component replacement, or adjustment) and resetting the equipment state, when an abnormality occurs in the product due to a change in process performance, on the assumption that the equipment state has changed. In addition, the process performance is held constant by empirically predicting the time when the process performance changes, and performing the maintenance of the equipment at regular intervals.

For example, Japanese Patent Application Laid-Open Publication No. H11(1999)-121440 (Patent Document 1), Japanese Patent Application Laid-Open Publication No. 2004-296612 (Patent Document 2), Japanese Patent Application Laid-Open Publication No. 2006-66552 (Patent Document 3), and Japanese Patent Application Laid-Open Publication No. 2014-107395 (Patent Document 4) disclose the methods for evaluating the state of the plasma equipment and the process performance by detecting the electrical changes (such as voltage, current, and impedance) of a RF power supplying line which supplies RF power to the process chamber.

In addition, the Patent Document 4, Japanese Patent Application Laid-Open Publication No. 2003-282542 (Patent Document 5), and Japanese Patent Application Laid-Open Publication No. 2004-228460 (Patent Document 6) disclose the methods for evaluating the state of the plasma equipment and the process performance by measuring the chamber-specific electrical characteristics (such as voltage, current, and impedance) determined by the geometrical configuration of the plasma equipment in the state where there is no plasma.

### SUMMARY OF THE INVENTION

In the techniques disclosed in Patent Documents 1, 2, 3, and 4 described above, although the equipment state can be determined to be abnormal from the change in the quantity of electricity, the abnormal part (component) cannot be immediately found since the equipment includes a plurality of components. In addition, when the abnormal part is identified, it takes a long time for the identification although the identification is possible in equipment with a small number of components. In equipment with a large number of components, the identification itself is difficult.

In addition, in the techniques disclosed in Patent Document 4, 5 and 6 described above, although the difference between the equipment states can be diagnosed from the change in the quantity of electricity, it cannot be directly diagnosed whether the process characteristics are abnormal or not. In addition, when the abnormal part (component) is identified, it takes a long time for the identification although the identification is possible in equipment with a small number of components. In a device with a large number of components, the identification itself is difficult. In addition, although there is also a method of identifying the abnormal part (component) by replacing the equipment with the electrical equivalent circuit and analyzing and calculating the circuit constants from the evaluation results, this method is also limited to the equipment with a small number of components and with a relatively simple structure. Even in this case, it takes time to perform the analysis.

The above and other objects and novel characteristics of the present invention will be apparent from the description of the present specification and the accompanying drawings.

A method of manufacturing a semiconductor device according to one embodiment includes a step of performing a plasma treatment on a semiconductor substrate by using plasma equipment, and a step of inspecting the plasma equipment. The inspection step includes a step of measuring impedance or reflection intensity at each frequency by varying a frequency of an input signal while regarding a RF power supplying line of the plasma equipment as an electrical circuit. Further, the inspection step includes a step of calculating characteristics of impedance or reflection intensity in an arrival location of the signal with respect to an arrival time of the signal by performing an inverse Fourier transform on a measurement result.

A method of manufacturing another semiconductor device according to one embodiment includes a step of inspecting plasma equipment when a plasma treatment is not performed on a semiconductor substrate. The inspection step includes a step of measuring impedance or reflection intensity at each frequency by varying a frequency of an input signal while regarding a RF power supplying line of the plasma equipment as an electrical circuit. Further, the inspection step includes a step of calculating characteristics of impedance or reflection intensity in an arrival location of the signal with respect to an arrival time of the signal or characteristics of impedance or reflection intensity in an arrival location of the signal with respect to an arrival distance of the signal by performing an inverse Fourier transform on a measurement result.

According to one embodiment, the identification of the abnormal part (component) can be performed in a short time.

### BRIEF DESCRIPTIONS OF THE DRAWINGS

FIG. 1 is a diagram for explaining a configuration of plasma CVD equipment in a first embodiment;

FIG. 2 is a diagram for explaining a method of diagnosing the abnormal component and the abnormal part in steps of inspecting the plasma CVD equipment in the first embodiment;

FIG. 3 is a flowchart for explaining a flow of the method of diagnosing the abnormal component and the abnormal part in the steps of inspecting the plasma CVD equipment in the first embodiment;

FIG. 4 is a diagram for explaining a case of the measurement and calculation results obtained when a plurality of pieces of the plasma CVD equipment are measured in the steps of inspecting the plasma CVD equipment in the first embodiment;

FIG. 5 is a diagram for explaining a case of the measurement and calculation results obtained when the results of FIG. 4 are verified in the steps of inspecting the plasma CVD equipment in the first embodiment;

FIG. 6 is a diagram for explaining a case of the measurement and calculation results obtained when the results of FIG. 5 are confirmed in the steps of inspecting the plasma CVD equipment in the first embodiment;

FIGS. 7A to 7C are diagrams for explaining a case of the measurement and calculation results in a conventional technique in comparison with the first embodiment;

FIGS. 8A to 8D are diagrams for explaining a method of manufacturing a semiconductor device using the plasma CVD equipment in the first embodiment;

FIGS. 9E to 9H are diagrams for explaining the method of manufacturing a semiconductor device using the plasma CVD equipment in the first embodiment, continued from FIGS. 8A to 8D;

FIGS. 10I to 10K are diagrams for explaining the method of manufacturing a semiconductor device using the plasma CVD equipment in the first embodiment, continued from FIGS. 9E to 9H;

FIGS. 11L to 11O are diagrams for explaining the method of manufacturing a semiconductor device using the plasma CVD equipment in the first embodiment, continued from FIGS. 10I to 10K;

FIG. 12 is a diagram for explaining a configuration of dry etching equipment in a second embodiment;

FIG. 13 is a diagram for explaining a method of diagnosing the abnormal component and the abnormal part in steps of inspecting dry etching equipment in the second embodiment;

FIG. 14 is a diagram for explaining a case of the measurement and calculation results obtained when a plurality of pieces of the plasma CVD equipment are measured in the steps of inspecting the dry etching equipment in the second embodiment; and

FIG. 15 is a diagram for explaining a configuration of plasma CVD equipment in a third embodiment.

### DESCRIPTIONS OF THE EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle.

Further, in the embodiments described below, it goes without saying that the components (including element steps) are not always indispensable unless otherwise stated or except the case where the components are apparently indispensable in principle.

Similarly, in the embodiments described below, when the shape of the component, positional relation thereof, and the like are mentioned, the substantially approximate and similar shapes and the like are included therein unless otherwise stated or except the case where it is conceivable that they are apparently excluded in principle. The same goes for the numerical value and the range described above.

[Summary of Embodiment]

A summary of the embodiment will be described. First, the techniques disclosed in Patent Documents 1 to 6 described above will be reviewed in detail.

In the techniques disclosed in Patent Documents 1, 2, 3, and 4 described above, although the device state can be determined to be abnormal from the change in the quantity of electricity, the abnormal part (component) cannot be immediately found since the equipment includes a plurality of components. In addition, when the abnormal part is identified, in equipment with a small number of components, it takes a long time for the identification although the identification is possible. In equipment with a large number of components, the identification itself is difficult.

Furthermore, even though the abnormality can be detected due to the change in the quantity of electricity in a case of an abnormality in a component (for example, a component such as an electrode having a large influence on the process performance), for example, when the component attached at the time of maintenance has the abnormality, the abnormality is not found until the equipment is started up and operated after the component is attached to the equipment followed by the measurement of the quantity of electricity, and therefore, the period of time from the attachment of the component to the starting up of the equipment is lost. Furthermore, the period of time for re-replacement of the component and restart of the equipment is also lost.

In addition, in the techniques disclosed in Patent Documents 4, 5 and 6 described above, although the difference between the equipment states can be diagnosed from the change in the quantity of electricity, it cannot be directly diagnosed whether the process characteristics are abnormal or not. In addition, when the abnormal part (component) is identified, in equipment with a small number of components, it takes a long time for the identification although the identification is possible. In equipment with a large number of components, the identification itself is difficult. In addition, although there is also a method of identifying the abnormal part (component) by replacing the equipment with the electrical equivalent circuit and analyzing and calculating the circuit constants from the evaluation results, this method is also limited to the equipment with a small number of components and with a relatively simple structure. Even in this case, it takes time to perform the analysis.

Furthermore, also in the techniques disclosed in Patent Documents 4, 5, and 6 as similar to Patent Documents 1, 2, and 3, in a case of an abnormality in the component, even though the abnormality can be detected due to the change in the quantity of electricity, for example, when the component attached at the time of maintenance has the abnormality, the abnormality is not found until the equipment is started up and operated after the component is attached to the equipment followed by the measurement of the quantity of electricity, and therefore, the period of time from the attachment of the component to the starting up of the equipment is lost. Furthermore, the period of time for re-replacement of the component and restart of the equipment is also lost.

In the plasma equipment of conventional techniques including Patent Documents 1 to 6 as described above, there are problems of the occurrence of the process defect due to the abnormality in the RF power supplying line (wafer scrap and yield loss), and the prolongation of its cause investigation and recovery of equipment (decrease in net working rate).

The present embodiment relates to a diagnosis technique for performing the early diagnosis on the presence or absence of the abnormality in the equipment, and for directly identifying a normal part when the equipment has the abnormality.

Specifically, the RF power supplying line of the plasma equipment is regarded as one type of the electrical circuits, and the frequency of the input signal is changed (varied), so that the impedance or reflection intensity at each frequency is measured. Moreover, the measurement results are subjected to an inverse Fourier transform, so that the characteristics of the impedance or reflection intensity in the arrival location of the signal with respect to the arrival time of the signal are calculated. Alternatively, the characteristics of the impedance or reflection intensity in the arrival location of the signal with respect to the arrival distance of the signal are calculated. As a result, by single measurement, the impedance or reflection intensity, which reflected the state of each component in the equipment, is obtained. Next, the characteristics of the impedance or reflection intensity which reflected the state of each component, or the value of impedance or reflection intensity which corresponded to the location of each component, and the characteristics of the impedance or reflection intensity in the arrival location of the signal with respect to the arrival time of the signal or the arrival distance of the signal are compared, so that the presence or absence of the abnormality is diagnosed and identified, and the abnormal part is diagnosed and identified when the equipment has the abnormality, the diagnosis and the identification being the first object. In addition, the difference among the components is quantitatively compared, and a quality or a degradation degree of each component (acceptability determination) is managed, so that the abnormality in the equipment is previously prevented, the prevention being the second object.

According to the present embodiment, in addition to the identification of the presence or absence of an abnormality in the equipment, the identification (classification) of the abnormal part (component), which is difficult in the conventional technique, can be performed in a short time. In addition, the abnormality of the single component and the abnormality in the attachment can be determined at the time of the equipment maintenance without the processes from the starting up of the equipment to the check of the process characteristics. In this manner, the downtime in the equipment abnormality can be significantly reduced, and the net working rate can be improved.

In addition, the present embodiment can also be utilized for the verification and improvement of process difference factors between the pieces of the equipment and the management of degradation degree of the component (acceptability determination) in a practical equipment. Thus, the equipment abnormality can be previously prevented, and the present invention can contribute to the reduction of the wafer scrap and to the yield improvement.

Hereinafter, each embodiment based on the above-described summary of the embodiments will be described in detail with reference to the accompanying drawings. Note that the same components are denoted by the same reference symbols throughout all the drawings for explaining the embodiments, and the repetitive description thereof will be omitted.

### First Embodiment

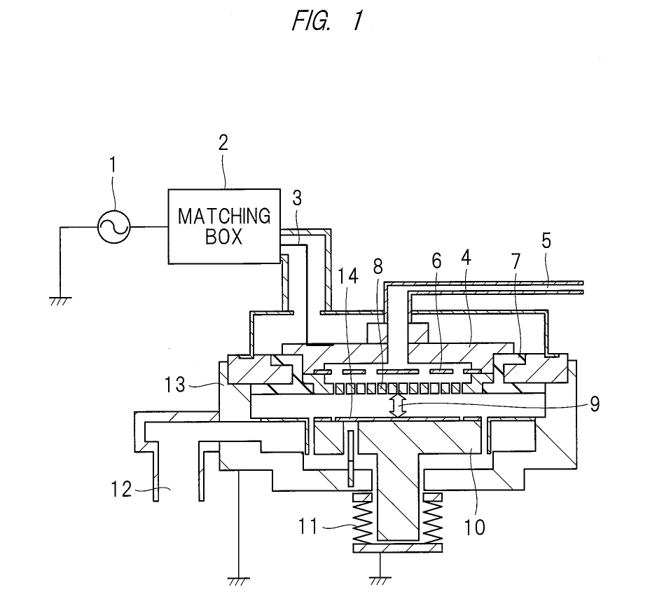

A method of manufacturing a semiconductor device using plasma equipment in the first embodiment will be described with reference to FIGS. 1 to 11. The first embodiment is applied to plasma CVD equipment as an example of the plasma equipment, and relates to a method of manufacturing a semiconductor device using the plasma CVD equipment.

<Plasma CVD Equipment>

FIG. 1 is a diagram for explaining a configuration of plasma CVD equipment in the present first embodiment. FIG. 1 illustrates a configuration of capacitively coupled plasma CVD equipment as an example.

The capacitively coupled plasma CVD equipment in the present first embodiment includes a RF power supply 1, a matching box 2, a feeder plate 3, a lid 4, a gas line 5, a gas distribution plate 6, an insulating ring 7, a gas plate 8, a gap 9, a susceptor heater 10, a bellows 11, an exhaust port 12, and a chamber 13. The RF power supply 1 is, for example, a power supply for outputting a RF power of 13.56 MHz.

As illustrated in FIG. 1, in the chamber 13 of the plasma CVD equipment, the susceptor heater 10 on which a wafer (semiconductor substrate) 14 is placed is provided. The susceptor heater 10 serves as a lower electrode for generating plasma. In addition, the susceptor heater 10 is connected to the bellows 11 provided on the outer wall portion of the chamber 13. The bellows 11 is fixed to the ground potential. In addition, the outer wall portion of the chamber 13 is fixed to the ground potential.

The gas line 5 for feeding the predetermined process gas into the chamber 13 is provided in the upper portion of the chamber 13. The gas distribution plate 6 and the gas plate 8 are provided in a portion of the gas line 5, from which the process gas is supplied into the chamber 13. The gas plate 8 serves as an upper electrode for generating the plasma. The RF power supply 1 is connected to the gas plate 8 through the lid 4 and the feeder plate 3. The matching box 2 for achieving the impedance matching is connected between the feeder plate 3 and the RF power supply 1.

The lid 4 and the gas plate 8 are electrically insulated from the outer wall portion of the chamber 13 by the insulating ring 7. The exhaust port 12 for exhausting the gas in the chamber 13 is provided in the lower portion of the chamber 13.

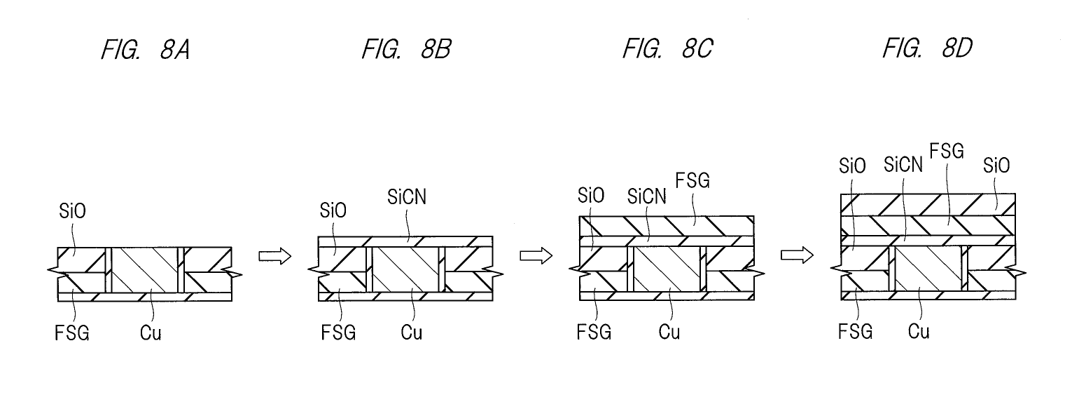

In the plasma treatment for the wafer 14 using the plasma CVD equipment in the present first embodiment, the process gas is supplied into the chamber 13 through the gas line 5. Furthermore, the RF power is supplied from the RF power supply 1 to the lid 4 and the gas plate 8 serving as the upper electrode through the matching box 2 and the feeder plate 3. Then, the plasma of the process gas is generated in the gap 9 between the gas plate 8 serving as the upper electrode and the susceptor heater 10 serving as the lower electrode, and the process gas is decomposed, so that the dielectric film such as SiO, SiN, and SiCN, or the metal film or others is formed on the wafer 14 placed on the susceptor heater 10. For example, FIGS. 8 to 11 described below illustrate an example of treatment steps of forming an interlayer dielectric film on a Cu wiring.

In the plasma CVD equipment as described in the present first embodiment, when the film formation is performed for a long period of time, various components such as the feeder plate 3, the lid 4, the gas plate 8, and the susceptor heater 10 to each of which the RF power is supplied are consumed and deteriorated, and the electrical contact state between the various components and the insulating state of the lid 4 electrically insulated from the chamber 13 by the insulating ring 7 are deteriorated due to the film deposition. As a result, the plasma characteristics of the equipment change, or the plasma becomes unstable, and therefore, the process performance deviates from the new state in the initial stage of the introduction or the normal state immediately after the maintenance, which results in the occurrence of the defects such that the predetermined film formation is not performed and electrical damage is delivered to the device.

In order to eliminate these defects, it is necessary to identify which component or part is abnormal among the components of each unit of the equipment, to replace the component, or to maintain the location. However, currently, there is no diagnostic method capable of directly identifying the abnormal component or part, and therefore, the component or part considered to have a problem is checked in order while being replaced one by one and being maintained. Alternatively, in the conventional technique, after the abnormal component or part is estimated by diagnosing the equipment difference of the whole equipment, the corresponding component is replaced or maintained.

However, in these methods, it takes a long time for the processes from the identification of the defective component or part to the elimination of the defects by the replacement or maintenance . Thus, in the present first embodiment, a method of diagnosing the abnormal component and the abnormal part described below is applied to the steps of inspecting the plasma CVD equipment.

<Method of Diagnosing Abnormal Component and Abnormal Part>

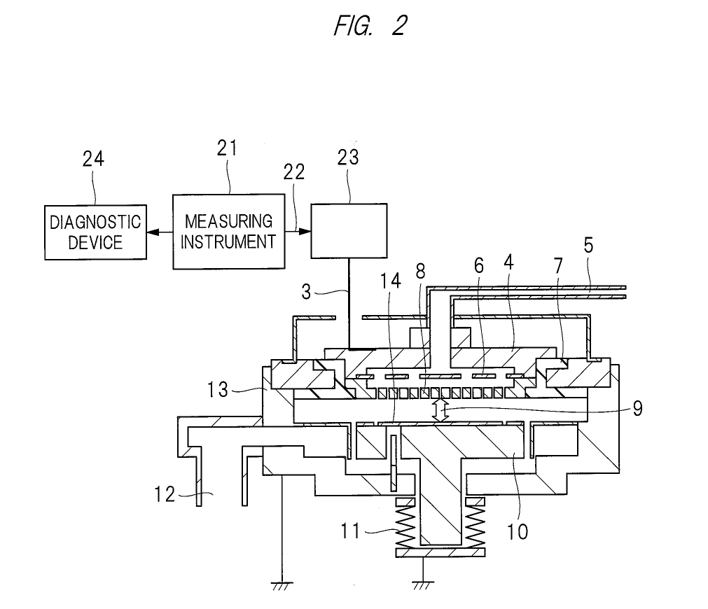

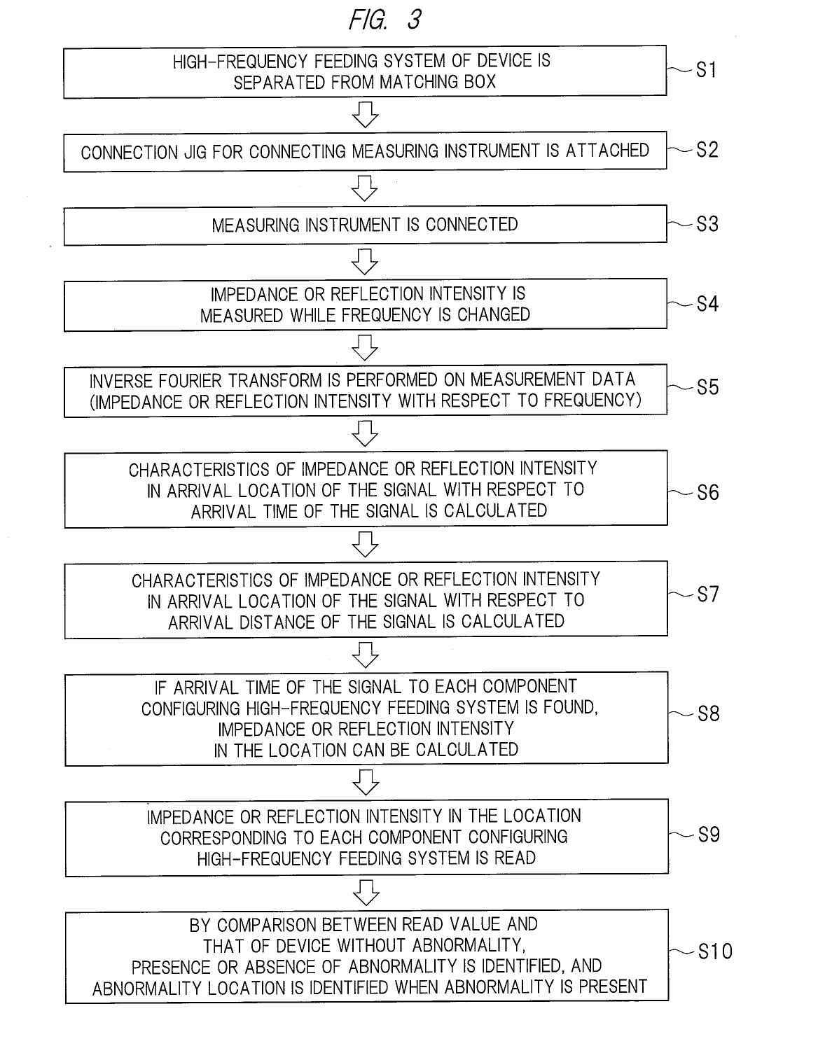

FIGS. 2 and 3 are diagrams for explaining the method of diagnosing the abnormal component and the abnormal part in the steps of inspecting the plasma CVD equipment in the present first embodiment. FIG. 2 is a diagram for explaining a diagnosis method of the plasma CVD equipment illustrated in FIG. 1 as an example. FIG. 3 is a flowchart for explaining a flow of the diagnosis method.

The steps of inspecting the plasma CVD equipment in the present first embodiment are performed when the step of performing the plasma treatment on the semiconductor substrate using the plasma CVD equipment is not performed, that is, when the plasma treatment is not performed on the semiconductor substrate.

In FIG. 3, first, the RF power supplying line of the plasma CVD equipment is disconnected from the matching box (step S1). That is, in the plasma CVD equipment illustrated in FIG. 1, the connection between the matching box 2 and the feeder plate 3 is disconnected. Furthermore, for the connection of the measuring instrument 21, the connection jig 23 is attached through the coaxial cable 22 if necessary (step S2). If not necessary, the connection jig 23 is not needed. Then, the measuring instrument 21 is connected to the RF power supplying line of the plasma CVD equipment by using the connection jig 23 (step S3). The configuration in the state after the step S3 is performed is as illustrated in FIG. 2.

In the connection using the connection jig 23 between the measuring instrument 21 and the RF power supplying line of the plasma CVD equipment, for example, one side of the connection jig 23 is attached to the feeder plate 3 in surface contact, and the other side thereof is to be a RF connector so that the coaxial cable 22 can be connected to the measuring instrument 21.

The measuring instrument 21 may be, for example, a signal generator capable of changing the waveform and its frequency, a display device such as an oscilloscope that can measure and display the input and output signals to the device, a network analyzer with a digital serial analyzer or a measurement function of the same type, a cheaper version of a simple measuring instrument, or others.

Next, the RF power supplying line of the plasma CVD equipment is regarded as one type of electrical circuits, and the frequency of the input signal is changed (varied) to measure the electrical characteristics at each frequency. Here, the case of measuring the impedance or the case of measuring the reflection intensity will be taken as an example of the electrical characteristics for the explanation. However, the case of measuring both the impedance and the reflection intensity may be acceptable.

In FIG. 3, first, in the measuring instrument 21, the frequency of the electrical input signal is changed, and the impedance or the reflection intensity of the equipment at each frequency at the time of the change is measured (step S4). At this time, in order to obtain the proper measurement results, it is desirable to change the measurement frequency from minimally several kHz to several hundred kHz up to maximally 1 to 5 GHz by an interval of 0.5 MHz or less, and to measure the impedance or reflection intensity at each frequency. More desirably, the measurement frequency is changed in the range from 300 kHz to 4 GHz by an interval of 0.3 MHz to measure the impedance or reflection intensity.

For example, the resolution with respect to the time and the distance decreases in the frequencies of maximally 1 GHz or less, and therefore, it is difficult to diagnose and identify the abnormal part from the measurement results. On the other hand, in the case of the frequencies of maximally 5 GHz or more, although the resolution with respect to the time and the distance increases, the input signal into the equipment is reflected and attenuated at the connection portion of the measuring instrument. Therefore, this case cannot obtain the accurate measurement results on which the state of each unit of the equipment containing the information of the abnormal location is reflected, and it is similarly difficult to diagnose and identify the abnormal part.

Next, a series of results (the impedance or reflection intensity with respect to the frequency) measured by the measuring instrument 21 are diagnosed by using a diagnostic device 24 such as a personal computer having a diagnostic function. The diagnostic device 24 is connected to, for example, the measuring instrument 21, and captures the measurement results of the measuring instrument 21 to perform the diagnosis. The configuration is not limited thereto, and the measuring instrument 21 and the diagnostic device 24 may be integrated. In addition, in the case of an independent diagnostic device, the method of capturing the measurement results of the measuring instrument 21 stored in a storage medium or others into the diagnostic device to perform the diagnosis may be used.

First, in the diagnostic device 24, an inverse Fourier transform is performed on the data (the impedance or reflection intensity with respect to the frequency) measured in the measuring instrument 21, so that the characteristics of the impedance or reflection intensity in the arrival location of the signal with respect to the arrival time of the signal is calculated (steps S5 and S6). The arrival time of the signal is the time when the signal input transmits from the measuring instrument 21 to reach the RF power supplying line. The impedance or reflection intensity in the arrival location of the signal is the impedance or reflection intensity in the arrival location of the signal to the RF power supplying line.

Furthermore, based on the characteristics of the impedance or reflection intensity in the arrival location of the signal with respect to the arrival time of the signal, the characteristics of the impedance or reflection intensity in the arrival location of the signal with respect to the arrival distance of the signal are calculated (step S7). The arrival distance of the signal can be obtained from a relation of “time×speed=distance” if a transmission speed in the RF power supplying line is obtained. Then, if the arrival time of the signal transmitting to each component configuring the RF power supplying line is obtained, the impedance or reflection intensity in the location can be calculated, and therefore, the impedance or reflection intensity in the location corresponding to each component constituting the RF power supplying line is read (steps S8 and S9). As a result, by single measurement, the impedance or reflection intensity, which reflected the state of each component of the RF power supplying line, is obtained.

Next, by comparison or others between the characteristics of the equipment having no abnormality and the characteristics of the impedance or reflection intensity which reflected the state of each component of the RF power supplying line, or the characteristics of the impedance or reflection intensity in the arrival location of the signal with respect to the arrival time of the signal or the arrival distance of the signal, the presence or absence of an abnormality is diagnosed, and the abnormal part is diagnosed and identified when the equipment has an abnormality (step S10). In the above-described manner, the presence or absence of an abnormality can be diagnosed, and the abnormal part can be diagnosed and identified when the equipment has an abnormality.

In addition, when it is found that the RF power supplying line has the abnormal part from the comparison results in step S10 in the steps of inspecting the plasma CVD equipment in the present first embodiment, for example, an alert can be raised. As a result, the operator can be notified of the presence of the abnormal part in the RF power supplying line.

In addition, from the change in the characteristics of the impedance or reflection intensity in the location on which the state of each component in the RF power supplying line is reflected which has been read in step S9, the contacted or insulated part of each component in the RF power supplying line and the state of each component can be individually diagnosed and managed. As a result, the difference in each component is quantitatively compared, and the quality or the degradation degree for each component is managed (as acceptability determination), so that the abnormality in the equipment can be previously prevented.

<Measurement and Calculation Results in First Embodiment>

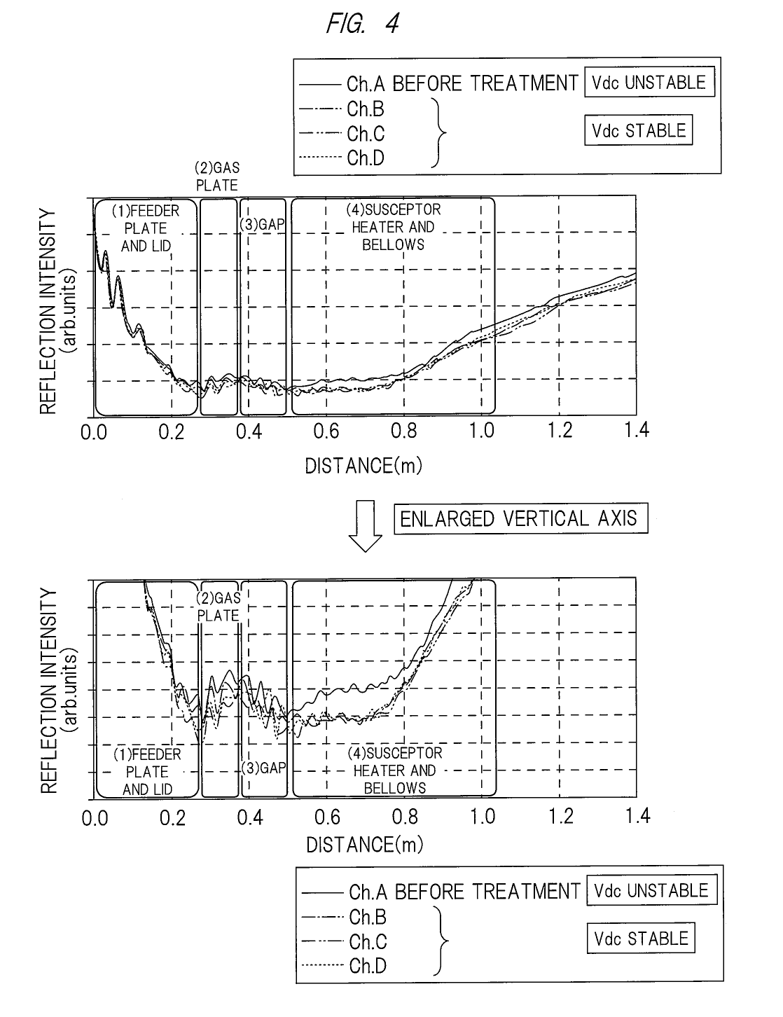

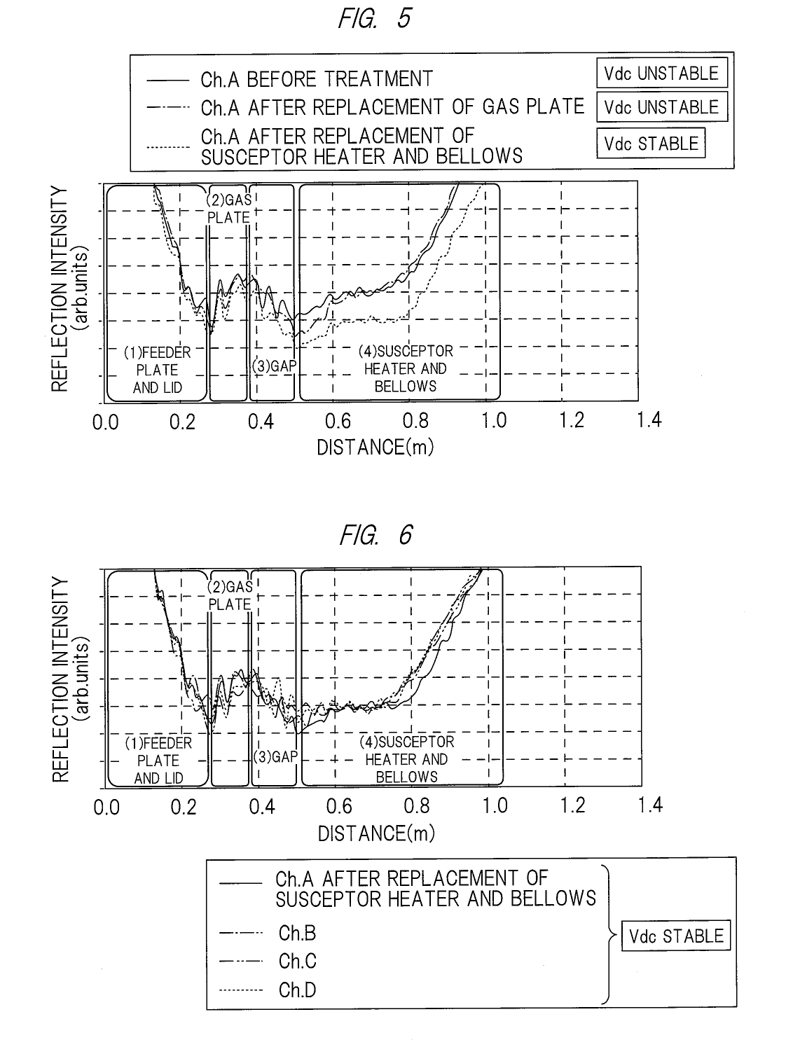

FIGS. 4 to 6 are diagrams for explaining the cases of the measurement and calculation results in the steps of inspecting the plasma CVD equipment in the present first embodiment. FIG. 4 is a case of the measurement and calculation results obtained when a plurality of plasma CVD equipments are measured, FIG. 5 is a case of the measurement and calculation results obtained when the results of FIG. 4 are verified, and FIG. 6 is a case of the measured and calculated results obtained when the results of FIG. 5 are confirmed.

FIG. 4 shows the case of the measurement and calculation results obtained when a plurality of capacitively coupled plasma CVD equipments of the same type as that of the first embodiment (Ch.A, Ch.B, Ch.C, and Ch.D) are practically measured. In FIG. 4, the lower diagram is an enlarged diagram of the vertical axis in the upper diagram so that the difference between the chambers is easy to understand. In each diagram, the horizontal axis represents the distance, and the vertical axis represents the reflection intensity. In this case, note that the horizontal axis represents the distance and the vertical axis represents the reflection intensity. However, of course, it is also possible to set the distance for the horizontal axis and the impedance for the vertical axis, set the time for the horizontal axis and the reflection intensity for the vertical axis, and set the time for the horizontal axis and the impedance for the vertical axis.

Here, the time described here is the time when the signal input from the measuring instrument 21 transmits through the equipment, and the distance described here is the distance in which the signal transmits through the equipment during the time. Therefore, the measurement results in FIG. 4 show the change in the reflection intensity in the direction of the distance of the RF power supplying line of the equipment from the location at which the measuring instrument 21 is connected. That is, in the measurement results in FIG. 4, waveform profiles of respective portions in the distance direction are considered to show (1) the state of the feeder plate 3 and the lid 4, (2) the state of the gas plate 8, (3) the state of the gap 9, and (4) the state of the susceptor heater 10 and the bellows 11 in ascending order of distance.

(1) In the state of the feeder plate 3 and the lid 4, the state of the electrical contact between the feeder plate 3 and the lid 4, and the state of the insulation from the chamber 13 by the insulating ring 7 can be obtained. (2) In the state of the gas plate 8, the state of the electrical contact between the gas plate 8 and the lid 4, and the state of the insulation from the chamber 13 by the insulating ring 7 can be obtained. (3) In the state of the gap 9, the state of the gap 9 between the gas plate 8 and the susceptor heater 10 can be obtained. (4) In the state of the susceptor heater 10 and the bellows 11, the state of the conduction from the susceptor heater 10 to the chamber 13 having the ground potential through the bellows 11 can be obtained.

In such characteristics of the change in the reflection intensity with respect to the distance, the correspondence between the distance shown in the horizontal axis and the distance of each unit of the practical equipment can be roughly taken when the chamber is opened to the atmosphere, and then, each unit is, for example, touched by hand in addition to the geometric structure and dimensions of the equipment.

In FIG. 4, the data obtained before the treatment for the Ch.A among the four pieces (Ch.A, Ch.B, Ch.C, and Ch.D) of the plasma CVD equipment represents the measurement results of the chamber with an unstable voltage Vdc that is one of parameters on which the state of the plasma is reflected, and the data of the Ch.B/C/D represents the measurement results of the chambers with a stable voltage Vdc. The unstable Vdc means that the state of the plasma is unstable. It can be found that the difference between the chambers with the stable Vdc and the chamber with the unstable Vdc is large in the portion corresponding to the gas plate 8, particularly, the periphery of the susceptor heater 10 and the bellows 11.

FIG. 5 shows the result in the Ch.A obtained from the case of the measurement and calculation results in FIG. 4, which is obtained by sequentially checking whether the gas plate 8, the susceptor heater 10, and the bellows 11 have the abnormality or not, and then, performing the measurement with the replacement in order to verify the location where the Vdc is an unstable factor. First, as the result of the check of the gas plate 8, although any particular abnormality has not been observed on the front and back surfaces, electrolytic corrosion has been observed on apart of the electrical contact surface with the lid 4, and therefore, the contact surface on the lid 4 side has been polished and removed, and the gas plate 8 has been replaced. However, there has been no large difference in the measurement results before and after the replacement, and the instability of the Vdc has not been improved, either. Next, in the checking of the susceptor heater 10 and the bellows 11, a large amount of deposition has been deposited between the susceptor heater 10 and the bellows 11. Thus, when the susceptor heater 10 and the bellows 11 have been replaced together, the reflection intensity in the corresponding location has been significantly reduced. In addition, the Vdc has been also stabilized as much as those of the Ch.B/C/D.

FIG. 6 shows a comparison between the measurement results obtained after the replacement of the susceptor heater 10 and the bellows 11 and the measurement results of the chambers Ch.B/C/D with a stable Vdc in the Ch.A obtained from the case of the measurement and calculation results in FIG. 5. It has been found out that the reflection intensity is reduced in the location corresponding to the gas plate 8, particularly, the periphery of the susceptor heater 10 and the bellows 11, which results in almost no difference. From the above-described results, it is considered that the electrical contact between the chamber body having the ground potential and the susceptor heater 10, the bellows 11, is deteriorated because a large amount of deposition is formed between the susceptor heater 10 and the bellows 11, and therefore, the Vdc is not stabilized.

<Measurement and Calculation Results in Conventional Technique in Comparison with First Embodiment>

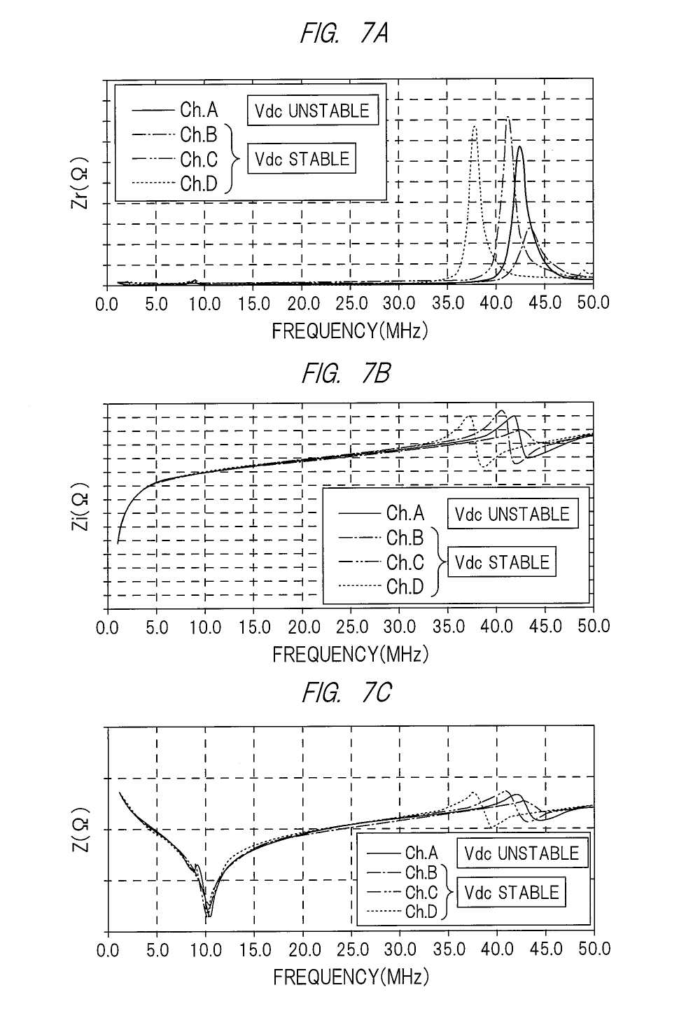

FIGS. 7A to 7C are diagrams for explaining cases of the measurement and calculation results in a conventional technique in comparison with the first embodiment. FIGS. 7A to 7C are cases of measurement of the frequency characteristics of the impedance measured in the conventional technique at the same time as when the Ch.A with the unstable Vdc and the Ch.B/C/D with the stable Vdc are measured by the method of the present first embodiment in a plurality of pieces of the capacitively coupled plasma CVD equipment in FIG. 2 for comparison with the method of the present first embodiment. In order from the top, FIG. 7A shows the frequency characteristics of the real part Zr of the impedance, FIG. 7B shows the frequency characteristics of the imaginary part Zi of the impedance, and FIG. 7C shows the frequency characteristics of the impedance Z having “F=300 kHz to 50 MHz”.

In all the results, it is found that there is a difference among the four chambers. However, it cannot be said that there is a certain tendency even in, for example, comparison in these results between the chamber with the stable Vdc and the chamber with the unstable Vdc. In addition, because of the method of collectively measuring the measurement objects, the consumption and degradation of each component and the degradation of the conducting and insulating state among various components cannot be obtained from the measurement results, and therefore, it is difficult to directly diagnose and identify the abnormal part from the results in the conventional technique.

<Method of Manufacturing Semiconductor Device>

FIGS. 8A to 11O are diagrams for explaining a method of manufacturing a semiconductor device using the plasma CVD equipment in the present first embodiment. FIGS. 8A to 11O show an example of a treatment step of forming the interlayer insulating film on the Cu wiring by the so-called the dual damascene process.

The dual damascene process is a technique of embedding a via hole and forming a wiring at the same time by previously forming trenches in portions to be the via hole and the wiring, by performing the metal embedding by deposition, and then, by removing the excess deposit portion by polishing.

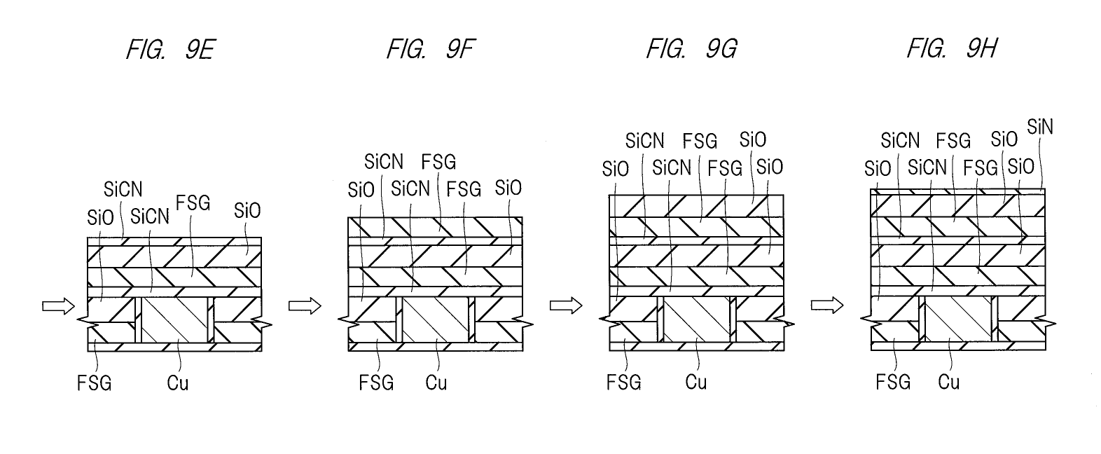

FIGS. 8A to 8D show treatment steps from FIG. 8A showing a state obtained after the CMP (Chemical Mechanical Polishing) treatment of the Cu wiring formed on the wafer, through FIG. 8B showing a state of the deposition treatment of the SiCN interlayer dielectric film, through FIG. 8C showing a state of the deposition treatment of the FSG interlayer dielectric film, to FIG. 8D showing a state of the deposition treatment of SiO interlayer dielectric film. As treatment steps continued from FIGS. 8A to 8D, FIGS. 9E to 9H show the treatment steps from FIG. 9E showing a state of the deposition treatment of SiCN interlayer dielectric film, through FIG. 9F showing a state of the deposition treatment of the FSG interlayer dielectric film, through FIG. 9G showing a state of the deposition treatment of the SiO interlayer dielectric film, to FIG. 9H showing a state of the deposition treatment of SiN interlayer dielectric film. In the CMP treatment of the Cu wiring, the surface of the Cu wiring is flattened. In each of the deposition treatments of the SiCN interlayer dielectric film, the FSG interlayer dielectric film, the SiO interlayer dielectric film, and the SiN interlayer dielectric film, each interlayer dielectric film of SiCN, FSG, SiO, and SiN is deposited.

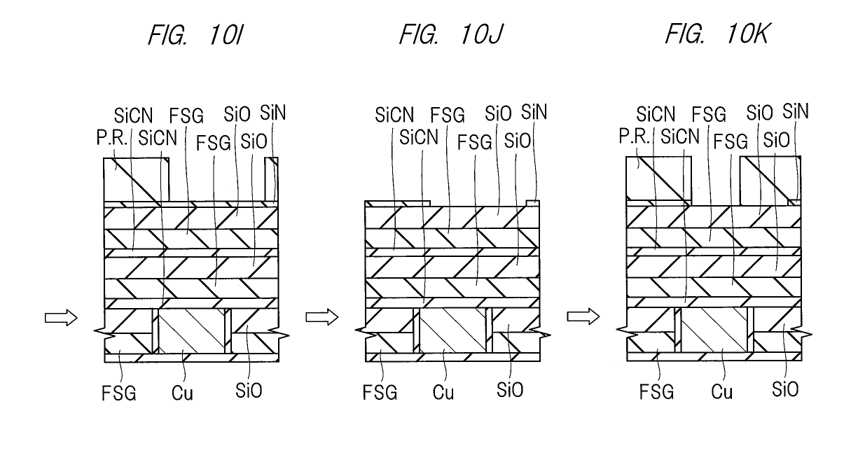

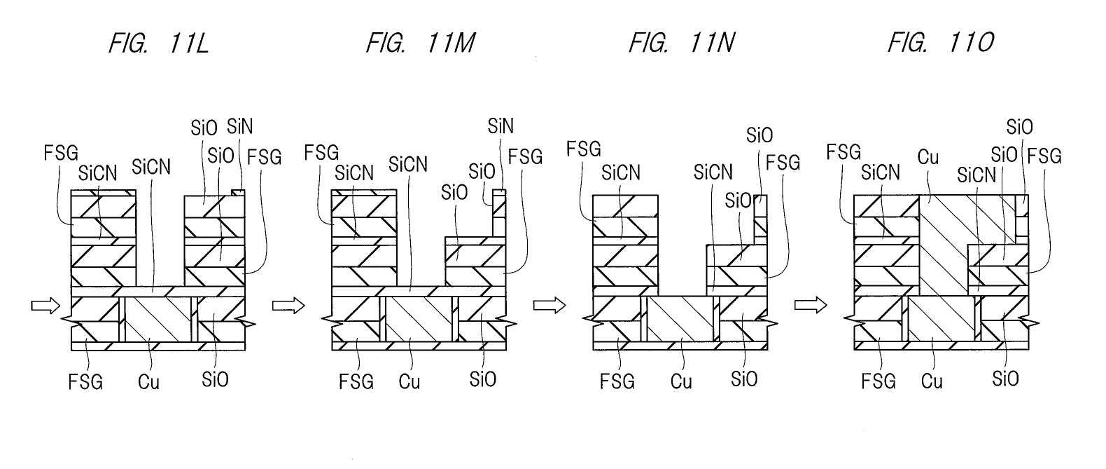

As treatment steps continued from FIGS. 9E to 9H, FIGS. 10I to 10K show the treatment step from FIG. 10I showing a state after the wiring photoresist treatment, through FIG. 10J showing the hard mask etching treatment, to FIG. 10K showing the via photoresist treatment. As treatment steps continued from FIGS. 10I to 10K, FIGS. 11L to 11O show the treatment steps from FIG. 11L showing the via hole etching treatment, through FIG. 11M showing the trench etching treatment, through FIG. 11N showing the SiCN etching treatment, to FIG. 11O showing the Cu metal embedding and Cu metal polishing treatments. In the wiring photoresist treatment and the via hole photoresist treatment, a photoresist film to be each mask for the wiring and the via hole is formed. In the hard mask etching treatment, the via hole etching treatment, the trench etching treatment, and the SiCN etching treatment, each of the hard mask, the via hole, the trench, and the SiCN is etched. In the Cu metal embedding and the Cu metal polishing treatment, the Cu metal is embedded in the trench, and then, the surface of the Cu metal is polished.

In the above-described example of the treatment steps of forming the interlayer dielectric film on the Cu wiring by the dual damascene process, the plasma CVD equipment in the present first embodiment is used when, for example, the deposition treatment of the SiCN interlayer dielectric film is performed. Of course, the plasma CVD equipment can be used also when the deposition treatments of forming the interlayer dielectric films of FSG, SiO, and SiN are performed.

<Effects of First Embodiment>

According to the present first embodiment described above, the abnormal component or part in the consumption and degradation of various components and the contacted and insulated state degradation among various components, which are difficult to be identified by the conventional technique, can be directly and quantitatively diagnosed and identified by single evaluation. As a result, the abnormal part (component), which is difficult to be identified by the conventional technique, can be identified (separated) in a short time at the time of the occurrence of the abnormality in the process and equipment.

In addition, the abnormality of the single component and the abnormality in the attachment can be determined at the time of the equipment maintenance without the processes from the starting up of the equipment to the check of the process characteristics. In this manner, the downtime in the process and equipment abnormality can be significantly reduced, and the net working rate can be improved.

In addition, the present embodiment can also be utilized for the verification and improvement of equipment difference factors between the pieces of the equipment and the management of degradation degrees of the single component, the conduction among various components, and the insulation state (acceptability determination) in practical equipment. Thus, the equipment abnormality can be previously prevented, and the present invention can contribute to the reduction of the wafer scrap and the yield improvement.

The details are as follows.

(1) By including the step S4 in the steps of examining the plasma CVD equipment, the RF power supplying line of the plasma CVD equipment is regarded as one type of the electrical circuits, the frequency of the input signal is varied, so that the impedance or reflection intensity at each frequency can be measured. Further, by including the steps S5 and S6, the measurement results are subjected to an inverse Fourier transform, so that the characteristics of the impedance or reflection intensity in the arrival location of the signal with respect to the arrival time of the signal can be calculated.

(2) By further including the step S7 in the steps of examining the plasma CVD equipment, the characteristics of the impedance or reflection intensity in the arrival location of the signal with respect to the arrival distance of the signal can be calculated based on the characteristics of the impedance or reflection intensity in the arrival location of the signal with respect to the arrival time of the signal.

(3) By further including the steps S8 and S9 in the steps of examining the plasma CVD equipment, the characteristics of the impedance or reflection intensity in a location on which a state of each component configuring the RF power supplying line is reflected can be calculated based on the characteristics of the impedance or reflection intensity in the arrival location of the signal with respect to the arrival time of the signal. Alternatively, the characteristics of the impedance or reflection intensity in a location on which a state of each component configuring the RF power supplying line is reflected can be calculated based on the characteristics of the impedance or reflection intensity in the arrival location of the signal with respect to the arrival distance of the signal.

(4) By further including the step S10 in the steps of examining the plasma CVD equipment, the characteristics of the impedance or reflection intensity in the location on which the state of each component configuring the RF power supplying line is reflected are compared with the characteristics of the equipment without the abnormality, so that the presence or absence of the abnormality of the RF power supplying line can be identified, and the abnormal part can be identified when the equipment has the abnormality.

(5) By further including the step S9 in the steps of examining the plasma CVD equipment, from the change in the characteristics of the impedance or reflection intensity configuring the location on which the state of each component in the RF power supplying line is reflected, the contacted or insulated part of each component in the RF power supplying line and the state of each component can be individually diagnosed and managed.

(6) As a result of further comparison in the step S10 in the steps of examining the plasma CVD equipment, an alert can be raised when it is found that the RF power supplying line has the abnormal part.

(7) By varying and measuring the frequency of the input signal in the range from 300 kHz to 4 GHz by the interval of 0.3 MHz when the impedance or reflection intensity is measured at each frequency, the accurate measurement results on which the state of each unit of the equipment containing the information of the abnormal part is reflected can be obtained without the decrease in the resolution with respect to the time and the distance.

### Second Embodiment

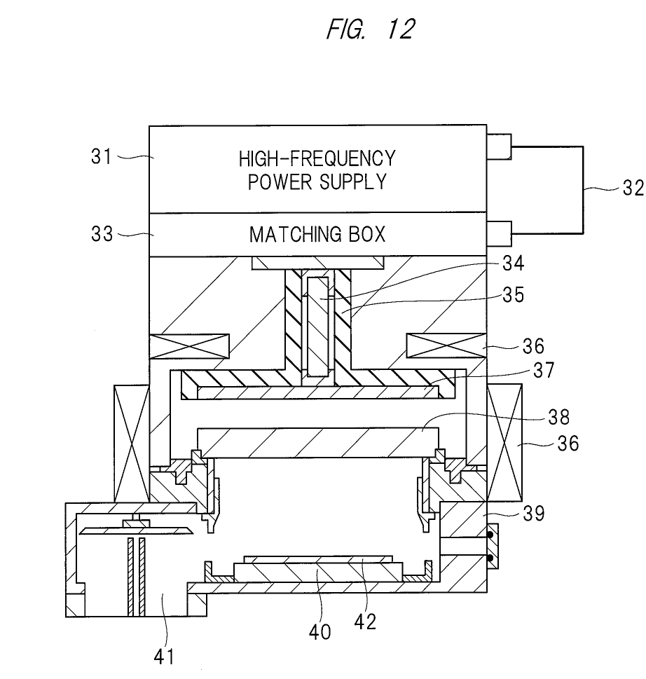

The method of manufacturing the semiconductor device using the plasma equipment in the second embodiment will be described with reference to FIGS. 12 to 14. The second embodiment is applied to dry etching equipment as an example of the plasma equipment, and relates to a method of manufacturing a semiconductor device using the dry etching equipment.

The first embodiment has described the method of the measurement by physically separating the matching box 2 from the RF power supplying line of the chamber body in the RF power supplying line, and connecting the measuring instrument 21 thereto through the connection jig 23. However, in practical plasma equipment, many pieces of equipment have physical difficulties in the separation of the matching box 2 from the RF power supplying line of the chamber body. In addition, even if they can be separated from each other, it is often necessary to design and manufacture the dedicated connection jig 23 as in the first embodiment. Furthermore, in this case, it takes time to separate the matching box 2 from the RF power supplying line of the chamber body, and to attach the connection jig 23.

Thus, as the second embodiment, a method of direct measurement through the matching box without the separation of the matching box from the RF power supplying line of the body will be described while exemplifying the case of diagnosing an ECR(Electron Cyclotron Resonance)-type dry etching equipment. In the present second embodiment, the points different from those of the first embodiment described above will be mainly described.

<Dry Etching Equipment>

FIG. 12 is a diagram for explaining a configuration of the dry etching equipment in the present second embodiment. FIG. 12 shows a configuration of an ECR-type dry etching equipment as an example.

The ECR-type dry etching equipment in the second embodiment includes a RF power supply 31, a coaxial cable 32, a matching box 33, a feeding component 34, an insulating component 35, a magnet 36, an electrode 37, a quartz window 38, a chamber 39, a stage 40, and an exhaust port 41. The RF power supply 31 is, for example, a power supply for outputting a RF power of 450 MHz.

As shown in FIG. 12, the stage 40 on which a wafer (semiconductor substrates) 42 is placed is arranged in the chamber 39 of the dry etching equipment. The electrode 37 is arranged in the upper portion of the chamber 39. In the chamber 39, the quartz window 38 is arranged between the electrode 37 and the stage 40 on which the wafer 42 is placed.

The RF power supply 31 is connected to the electrode 37 through the feeding component 34. The matching box 33 for achieving the impedance matching is connected between the feeding component 34 and the RF power supply 31. The RF power supply 31 and the matching box 33 are connected to each other by the coaxial cable 32.

The electrode 37 is electrically insulated from the outer wall portion of the chamber 39 by the insulating component 35. The magnet 36 for generating the ECR is arranged on the outer wall portion of the chamber 39. The exhaust port 41 for exhausting the gas in the chamber 39 is arranged in the lower portion of the chamber 39.

In the plasma treatment using the dry etching equipment in the second embodiment for the wafer 42, the process gas is supplied into the chamber 39 through the gas line, and the pressure in the chamber 39 is adjusted by the valve for pressure adjustment in the exhaust port 41. Furthermore, the RF power is supplied from the RF power supply 31 to the electrode 37 insulated from the chamber 39 through the coaxial cable 32, the matching box 33, and the feeding component 34 insulated with the insulating component 35. Then, the plasma of the process gas is generated between the electrode 37 and the stage 40, and the wafer 42 placed on the stage 40 is etched by the ions generated at the place.

The dry etching equipment in the present second embodiment can be used when each etching treatment is performed in, for example, the example of the treatment step by the dual damascene process shown in FIGS. 8A to 11O in the first embodiment.

Even in the dry etching equipment as in the present second embodiment, when the etching treatment is performed for a long time as similar to the case of the first embodiment, various components such as the feeding component 34, the electrode 37, and the stage 40 to each of which RF power is supplied are consumed and degraded, and the contacting state and the insulating state among various components are degraded due to the heating caused from the RF power, the corrosion caused from the etching, the adhesion of by-products, and others. As a result, the plasma characteristics of the equipment change, or the plasma becomes unstable, and therefore, the process performance is changed from a new state in an initial stage of the introduction or from a normal state obtained immediately after the maintenance, and such defects as not performing the predetermined etching occur.

In addition, by the change of the impedance of the RF power supplying line, the matching cannot be made in the matching box 33, the reflected power is increased, and an error occurs.

In order to eliminate these defects, it is necessary to identify which component or part is abnormal among the components of each unit of the equipment, to replace the component, or to maintain the part. However, currently, there is no diagnostic method of directly identifying the abnormal component or part. Therefore, the checking is made by replacing the component or part considered to have an abnormality one by one in order or maintaining the component or part, or the corresponding component is replaced or maintained based on the diagnosis of the machine difference as the whole equipment by the conventional technique to estimate the abnormal component or part.

However, in these methods, it takes a long time from the identification of the defective component or part to the elimination of the defects by the replacement or maintenance. Thus, in the present second embodiment, a method of diagnosing the abnormal component and the abnormal part described below is applied in the steps of inspecting the dry etching equipment.

<Method of Diagnosing Abnormal Component and Abnormal Part>

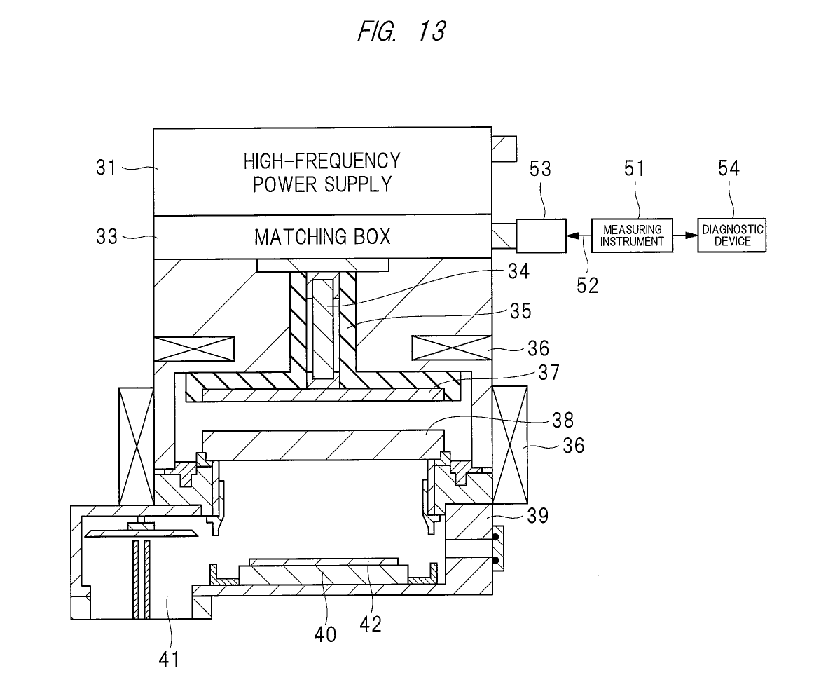

FIG. 13 is a diagram for explaining the method of diagnosing the abnormal component and the abnormal part in the steps of inspecting the dry etching equipment in the present second embodiment. FIG. 13 is a diagram for explaining the diagnosis method while exemplifying the dry etching equipment shown in FIG. 12.

In the first embodiment, the measurement is performed by physically separating the RF power supplying line of the equipment body from the matching box, and connecting the measuring instrument to the RF power supplying line of the equipment through the coaxial cable by using the connection jig or others. On the other hand, in the second embodiment, the RF power supplying line of the equipment is measured together with the electrical circuit of the matching box 33 by not separating the matching box 33 but disattaching the coaxial cable 32 which connects the RF power supply 31 and the matching box 33, attaching the connection jig 53 to the input side of the matching box 33, and connecting the measuring instrument 51 through the coaxial cable 52.

As similar to the first embodiment, the measuring instrument 51 may be a signal generator capable of changing the waveform and its frequency and a display device such as an oscilloscope such as can measure and display the input and output signals to the device, a network analyzer such as a digital serial analyzer and as having a measurement function of the same type, a simple measuring instrument of a cheaper version, or others.

As similar to the first embodiment, also for the measurement conditions, it is desirable to change the measurement frequency from minimally several kHz to several hundred kHz up to maximally 1 to 5 GHz by an interval of 0.5 MHz or less. More desirably, the measurement frequency is changed in the range from 300 kHz to 4 GHz by an interval of 0.3 MHz for the measurement. In this case, circuit constants of variable elements of the electrical circuit in the matching box 33 are set to be the same as each other.

Furthermore, a series of results measured by the measuring instrument 51 (the impedance or reflection intensity with respect to the frequency) are diagnosed by using a diagnostic device 54 such as a personal computer having a diagnostic function as similar to the first embodiment. In this manner, the characteristics of the impedance or reflection intensity in the arrival location of the signal with respect to the arrival time of the signal, the characteristics of the impedance or reflection intensity in the arrival location of the signal with respect to the arrival distance of the signal, and the characteristics of the impedance or reflection intensity in a location on which a state of each component in the RF power supplying line is reflected can be obtained.

<Measurement and Calculation Results in Second Embodiment>

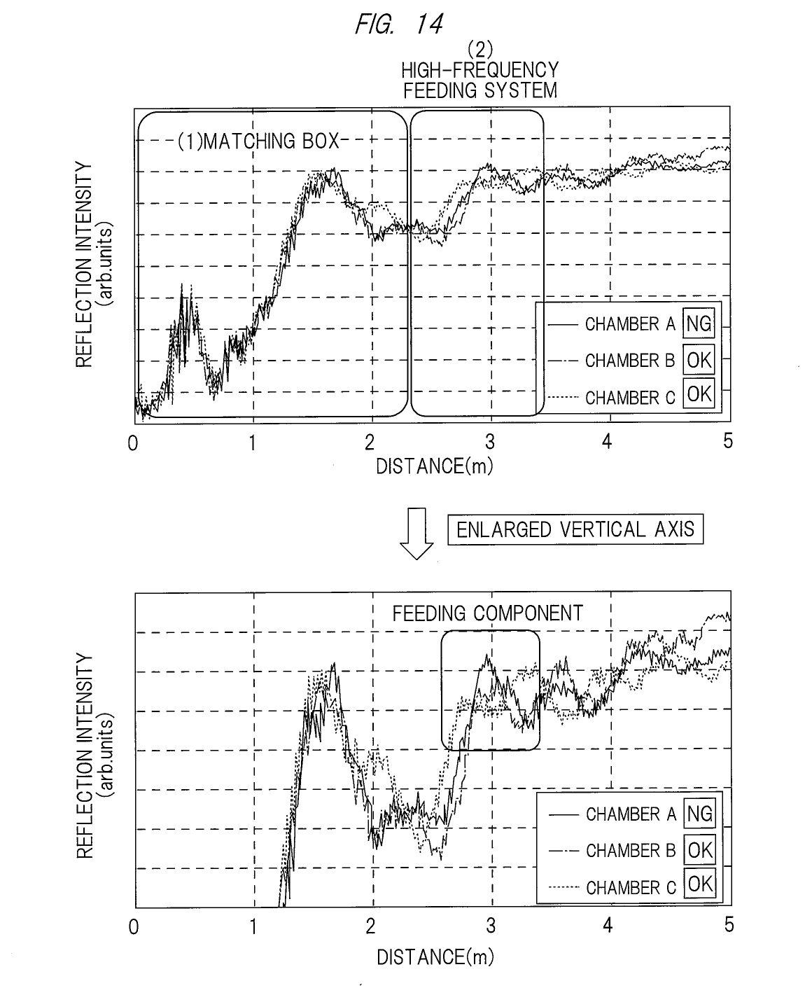

FIG. 14 is a diagram for explaining the case of the measurement and calculation results in the steps of inspecting the dry etching equipment in the present second embodiment. FIG. 14 shows the case of the measurement and calculation results obtained when a plurality of pieces (chamber A, chamber B, and chamber C) of ECR-type dry etching equipment of the same type as that of the second embodiment are practically measured. In the lower diagram of FIG. 14, the vertical axis in the upper diagram is enlarged so that the difference between the chambers is easy to understand. Each horizontal axis represents the distance, and each vertical axis represents the reflection intensity. Note that, although the horizontal axis represents the distance and the vertical axis represents the reflection intensity in this case, it is, of course, also possible that the horizontal axis represents the distance and the vertical axis represents the impedance, that the horizontal axis represents the time and the vertical axis represents the reflection intensity, or that the horizontal axis represents the time and the vertical axis represents the impedance.

The measurement results in FIG. 14 show the change in the reflection intensity in the distance direction of the RF power supplying line of the equipment from the location connected to the measuring instrument 51. That is, in the measurement results in FIG. 14, it is considered that the waveform profile of each location with respect to the distance direction shows (1) the state of the electrical circuit from the input unit to the output unit of the matching box 33, and (2) the contacting and insulating state of the feeding component 34 and the electrode 37 of the RF power supplying line beyond the output unit of the matching box 33 in ascending order of distance.

In the dry etching equipment in the present second embodiment, by the repeat of the feeding of the RF power, for example, the feeding component 34 is heated, the surface is oxidized, and therefore, the electrical contacting states between it and the matching box 33 and between it and the electrode 37 are degraded, and the supply power is consumed by ones other than the plasma. As a result, the defects in the process and the equipment occur. The measurement result of the chamber A shows a (NG) result obtained by practical measurement in a state with the occurrence of defects because of the degradation of the electrical contact of the feeding component 34. As for the chamber A, the equipment defects are eliminated after the component is replaced with a new component. The measurement results of the chambers B and C are (OK) results obtained in a state without the degradation of the contacting state.

As for the contacting and insulating states of the feeding component 34 and electrode 37, it is considered that the smaller the value is, the better the contacting state is. In the review of the present measurement case, the value of the chamber A is high while the values of the chambers B and C are similar to each other, which results in showing the degradation of the contacting state. Therefore, even by such measurement as including the matching box 33, the degradation of the electrical contact of the feeding component 34 can be diagnosed and identified.

<Effects of Second Embodiment>

According to the present second embodiment described above, the abnormal component or portion, the abnormal component or part with the consumption and degradation of various components and the degradation of the contacting and insulating states among various in such measurement as including the matching box 33 can be directly and quantitatively diagnosed and identified in a single evaluation, the diagnosis and identification being difficult in a conventional technique. Thus, in addition to the effects described in the first embodiment, the measuring time is significantly reduced, and easier measurement can be performed by such measurement as including the matching box 33, since it is not necessary to physically separate the matching box 33 from the RF power supplying line of the body and to design and manufacture the dedicated connection jig. As a result, the downtime in the process and the occurrence of the equipment abnormality can be further reduced than the first embodiment, so that the net working rate can be further improved.

### Third Embodiment

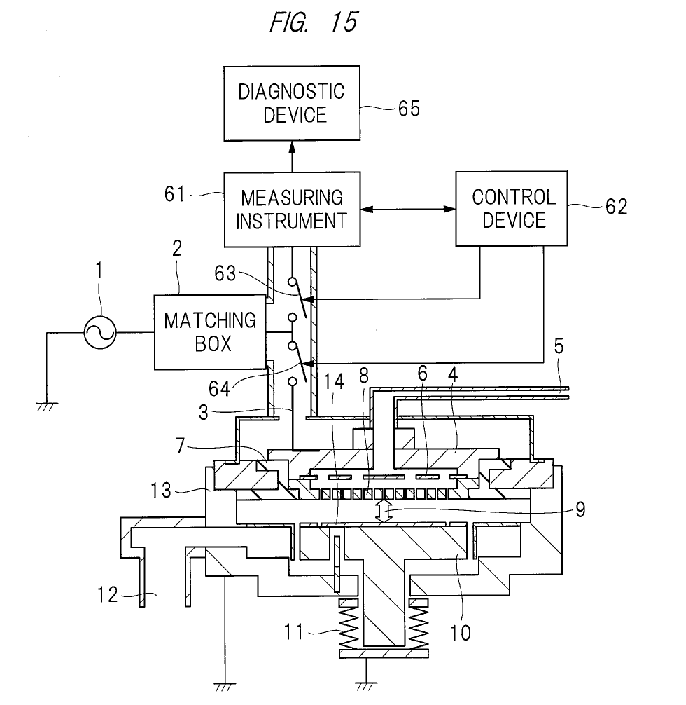

A method of manufacturing a semiconductor device using plasma equipment in the third embodiment will be described with reference to FIG. 15. As similar to the first embodiment, the third embodiment is applied to capacitively coupled plasma CVD equipment as an example of the plasma equipment, and relates to a method of manufacturing a semiconductor device using the plasma CVD equipment. In the present third embodiment, the points different from those of the first embodiment described above will be mainly described.

The present third embodiment is an example of capacitively coupled plasma CVD equipment embedded with a system which automatically diagnoses and manages the abnormal component or part with the consumption and degradation of various components and the degradation of the contacting and insulating states among various components, and besides, automatically performs the processes from the abnormality determination to the raising of the alert.

<Plasma CVD Equipment>

FIG. 15 is a diagram for explaining a configuration of the plasma CVD equipment in the third embodiment. As similar to the first embodiment, FIG. 15 shows a configuration of capacitively coupled plasma CVD equipment as an example.

The capacitively coupled plasma CVD equipment in the present third embodiment has a configuration with a measuring instrument 61, a control device 62, relays 63 and 64, and a diagnostic device 65 in addition to the configuration shown in FIG. 1 of the first embodiment. The measuring instrument 61 is connected to the feeder plate 3 through the relays 63 and 64. The matching box 2 to which the RF power supply 1 is connected is connected to the feeder plate 3 through the relay 64. The control device 62 controls the measuring instrument 61 and the ON/OFF of the relays 63 and 64.

As shown in FIG. 15, the measuring instrument 61 is placed in the RF power supplying line of the plasma CVD equipment through the relays 63 and 64, and the relays 63 and 64 are turned ON by the control from the control device 62 when the plasma treatment is regularly not performed, so that the impedance or reflection intensity with respect to the frequency is measured in the measuring instrument 61. Then, the diagnostic device 65 compares the value of the impedance or reflection intensity corresponding to each of a plurality of units of the equipment obtained from the measurement results with the previously-set standard for each unit, and determines the degradation of the contacting and insulating states of the component in the unit when the value is out of the standard, and raises the alert.

In addition, when the plasma treatment is performed, the relay 63 is turned OFF so that the measuring instrument 61 is protected from the RF power fed from the RF power supply 1. In this manner, also in the configuration embedded with the system, which automatically performs the processes of the diagnosis and the management, and besides, the processes from the abnormality determination to the raising of the alert, the plasma treatment can be performed in the state in which the measuring instrument 61 is electrically insulated.

As described above, the plasma CVD equipment shown in FIG. 15 includes functions which automatically identify the presence or absence of the abnormality of the RF power supplying line and a location of the abnormality when the equipment has the abnormality, which individually diagnose and manages the contacted or insulated part of each component of the RF power supplying line and the state of each component, and which raise the alert when the RF power supplying line has the abnormal part.

<Effects of Third Embodiment>

According to the present second embodiment described above, the abnormal component or part such as the consumption and degradation of various components and the degradation of the contacting and insulating states among various can be automatically directly and quantitatively diagnosed and identified in a single evaluation, the diagnosis and identification being difficult in a conventional technique. Thus, in addition to the effects described in the first embodiment, the measuring time is significantly reduced, and easier measurement can be performed by the automatic measurement, since it is not necessary to separate the matching box 2 from the RF power supplying line of the body physically and to design and manufacture the dedicated connection jig. As a result, the downtime in the process and the occurrence of the equipment abnormality can be further reduced than the first embodiment, so that the networking rate can be further improved.

In the foregoing, the invention made by the present inventors has been concretely described based on the embodiments. However, it is needless to say that the present invention is not limited to the foregoing embodiments and various modifications and alterations can be made within the scope of the present invention.

For example, in the above-described embodiments, the cases in which the present invention is applied to the capacitively coupled plasma CVD equipment and to the ECR-type dry etching equipment have been described as an example of the plasma equipment. However, the present invention is not limited to them, and is also applicable to other plasma CVD equipment and dry etching equipment.

Furthermore, the present invention can be widely applied to the whole plasma equipment for performing various treatments by using plasma such as etching, CVD, and sputtering.

In addition, the above-described embodiments have concretely described the present invention so that the present invention can be easily understood, and thus, the present invention is not necessarily limited to the one including all the described configurations. In addition, a part of the structure of one embodiment can be replaced with the structure of the other embodiment, and besides, the structure of the other embodiment can be added to the structure of one embodiment. Further, the other structure can be added to/eliminated from/replaced with a part of the structure of each embodiment.

What is claimed is:

1. A method of manufacturing a semiconductor device comprising steps of:
(a) performing a plasma treatment on a semiconductor substrate by using plasma equipment; and
(b) inspecting the plasma equipment,
wherein the step of (b) includes steps of:
(b1) measuring impedance or reflection intensity at each frequency by varying a frequency of an input signal while regarding a RF power supplying line of the plasma equipment as an electrical circuit; and
(b2) calculating characteristics of impedance or reflection intensity in an arrival location of the signal with respect to an arrival time of the signal by performing an inverse Fourier transform on a measurement result in the step of (b1).

2. The method of manufacturing the semiconductor device according to claim 1,
wherein the step of (b) further includes a step of
(b3) calculating characteristics of impedance or reflection intensity in a location, on which a state of each component configuring the RF power supplying line is reflected, based on the characteristics of the impedance or reflection intensity in the arrival location of the signal with respect to the arrival time of the signal calculated in the step of (b2).

3. The method of manufacturing the semiconductor device according to claim 2,
wherein the step of (b) further includes a step of
(b4) identifying presence or absence of an abnormality in the RF power supplying line, and an abnormal part when the RF power supplying line has an abnormality, by comparing characteristics of equipment having no abnormality and the characteristics of the impedance or reflection intensity in the location on which the state of each component configuring the RF power supplying line is reflected, calculated in the step of (b3).

4. The method of manufacturing the semiconductor device according to claim 2,
wherein the step of (b) further includes a step of
(b5) performing management by individually diagnosing a conducting or insulating location of each component in the RF power supplying line and a state of each component from a change in the characteristics of the impedance or reflection intensity in the location on which the state of each component configuring the RF power supplying line is reflected, calculated in the step of (b3).

5. The method of manufacturing the semiconductor device according to claim 3,
wherein the step of (b) further includes a step of
(b6) raising an alert when it is found that the RF power supplying line has the abnormal part as a result of the comparison in the step of (b4).

6. The method of manufacturing the semiconductor device according to claim 1,
wherein the step of (b) further includes a step of
(b11) calculating characteristics of impedance or reflection intensity in an arrival location of the signal with respect to an arrival distance of the signal, based on the characteristics of the impedance or reflection intensity in the arrival location of the signal with respect to the arrival time of the signal calculated in the step of (b2).

7. The method of manufacturing the semiconductor device according to claim 6,
wherein the step of (b) further includes a step of
(b12) calculating characteristics of impedance or reflection intensity in a location, on which a state of each component configuring the RF power supplying line is reflected, based on the characteristics of the impedance or reflection intensity in the arrival location of the signal with respect to the arrival distance of the signal calculated in the step of (b11).

8. The method of manufacturing the semiconductor device according to claim 7,
wherein the step of (b) further includes a step of
(b13) identifying presence or absence of an abnormality in the RF power supplying line, and an abnormal part when the RF power supplying line has an abnormality, by comparing characteristics of equipment having no abnormality and the characteristics of the impedance or reflection intensity in the location on which the state of each component configuring the RF power supplying line is reflected, calculated in the step of (b12).

9. The method of manufacturing the semiconductor device according to claim 7,
wherein the step of (b) further includes a step of
(b14) performing management by individually diagnosing a conducting or insulating location of each component in the RF power supplying line and a state of each component from a change in the characteristics of the impedance or reflection intensity in the location on which the state of each component configuring the RF power supplying line is reflected, calculated in the step of (b12).

10. The method of manufacturing the semiconductor device according to claim 8,
wherein the step of (b) further includes a step of
(b15) raising an alert when it is found that the RF power supplying line has the abnormal part as a result of the comparison in the step of (b13).

11. The method of manufacturing the semiconductor device according to claim 1,
wherein, in the step of (b1), the impedance or the reflection intensity is measured while a frequency of the input signal is varied in a range from 300 kHz to 4 GHz by an interval of 0.3 MHz.

12. The method of manufacturing the semiconductor device according to claim 1,
wherein the plasma equipment includes functions of identifying presence or absence of an abnormality of the RF power supplying line, and an abnormal part when the RF power supplying line has the abnormality, performing management by individually diagnosing a contacting or insulating location of each component in the RF power supplying line and a state of each component, and raising an alert when the RF power supplying line has the abnormal part.

13. A method of manufacturing a semiconductor device comprising a step of
(a) inspecting plasma equipment when a plasma treatment is not performed on a semiconductor substrate,
wherein the step of (a) includes steps of:
(a1) measuring impedance or reflection intensity at each frequency by varying a frequency of an input signal while regarding a RF power supplying line of the plasma equipment as an electrical circuit; and
(a2) calculating characteristics of impedance or reflection intensity in an arrival location of a signal with respect to an arrival time of the signal or characteristics of impedance or reflection intensity in an arrival location of the signal with respect to an arrival distance of the signal by performing an inverse Fourier transform on a measurement result in the step of (a1).

14. The method of manufacturing the semiconductor device according to claim 13,
wherein the step of (a) further includes a step of
(a3) calculating the characteristics of the impedance or reflection intensity in the location on which the state of each component configuring the RF power supplying line is reflected, based on characteristics of impedance or reflection intensity in a location on which a state of each component configuring the RF power supplying line is reflected, based on characteristics of impedance or reflection intensity in an arrival location of a signal with respect to an arrival time of the signal or characteristics of impedance or reflection intensity in an arrival location of the signal with respect to an arrival distance of the signal calculated in the step of (a2).

15. The method of manufacturing the semiconductor device according to claim 14,
wherein the step of (a) further includes a step of
(a4) identifying presence or absence of an abnormality in the RF power supplying line, and an abnormal part when the RF power supplying line has an abnormality, by comparing characteristics of equipment having no abnormality and the characteristics of the impedance or reflection intensity in the location on which the state of each component configuring the RF power supplying line is reflected, calculated in the step of (a3).

16. The method of manufacturing the semiconductor device according to claim 14,
wherein the step of (a) further includes a step of
(a5) performing management by individually diagnosing a conducting or insulating location of each component in the RF power supplying line and a state of each component from a change in the characteristics of the impedance or reflection intensity in the location on which the state of each component configuring the RF power supplying line is reflected, calculated in the step of (a3).

17. The method of manufacturing the semiconductor device according to claim 15,
wherein the step of (a) further includes a step of
(a6) raising an alert when it is found that the RF power supplying line has the abnormal part as a result of the comparison in the step of (a4).
